(19) United States
(12) Patent Application Publication
(10) Pub. No.: US 2013/0064027 A1
(43) Pub. Date: Mar. 14, 2013

(54) Memory and Method of Adjusting Operating Voltage thereof

(71) Applicants: Meng-Yi Wu, Kaohsiung City (TW); Wein-Town Sun, Taoyuan County (TW); Yen-Tai Lin, Hsin-Chu City (TW); Cheng-Jye Liu, Hsinchu County (TW); Chiun-Chi Shen, Hsinchu County (TW)

(72) Inventors: Meng-Yi Wu, Kaohsiung City (TW); Wein-Town Sun, Taoyuan County (TW); Yen-Tai Lin, Hsin-Chu City (TW); Cheng-Jye Liu, Hsinchu County (TW); Chiun-Chi Shen, Hsinchu County (TW)

(21) Appl. No.: 13/231,980

(22) Filed: Sep. 14, 2011

(51) Int. Cl. G11C 29/00

(52) U.S. Cl. 365/201

(57) ABSTRACT

By adjusting an operating voltage of a memory cell in a memory according to a measured capacitance result indicating capacitance of an under-test capacitor of the memory cell, an appropriate operating voltage for the memory cell can always be determined according to the measured capacitance result. The measured capacitance result indicates whether the capacitance of the under-test capacitor indicating the characteristic of the gate dielectric of the memory cell is higher or lower than a reference capacitor, and is generated by amplifying a difference between two voltages indicating capacitance of the reference capacitor and the capacitance of the under-test capacitor.

### BACKGROUND OF THE INVENTION

1. Field of the Invention

The present invention discloses a memory and a method of adjusting the operating voltage of a memory cell in the memory thereof, and more particularly, to a memory and a method of adjusting the operating voltage of a memory cell of the memory according to a gate length or a gate dielectric thickness of the memory cell.

2. Description of the Prior Art

In the fabrication of a memory cell, properties of a memory cell, such as an Oxide-Nitride-Oxide (ONO) thickness (may also be referred to a gate dielectric thickness) and a gate length (may be abbreviated as PolyCD), act as critical factors. Qualities of a fabricated memory cell are indicated by program/erase window and data retention. The program/erase window is determined by whether a program/erase voltage for biasing is precise enough to tell a logic-high voltage or a logic low voltage. Whether the data retention is kept or not is also determined by the program/erase voltage.

However, since there is process variation introduced in fabrication of memory cells, the gate dielectric thickness or the gate length of different memory cells may be variant, and this phenomenon will introduce imprecise program/erase voltages as well. Moreover, if the fabrication process is specifically adjusted for accommodating every possible variation, it must be a huge waste of time and fabrication capitals.

### SUMMARY OF THE INVENTION

The claimed invention discloses a memory. The memory comprises a memory cell, an electrical oxide testing circuit, and an operating voltage adjusting module. The electric oxide testing circuit is utilized for measuring capacitance of an under-test capacitor of the memory cell, so as to generate a measured capacitance result. The operating voltage adjusting module is utilized for adjusting the operating voltage of the memory cell according to the measured capacitance result.

The claimed invention also discloses a method for determining an operating voltage of a memory cell. The method comprises measuring a characteristic of the gate dielectric of the memory cell by measuring under-test capacitance of an under-test capacitor of the memory cell to generate a measured capacitance result; and adjusting the operating voltage of the memory cell according to the measured capacitance result. In the claimed invention, the characteristic of the gate oxide may refer to a gate dielectric thickness or a gate length.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of a memory according to an embodiment of the present invention.

FIG. 2 illustrates the electrical oxide testing circuit shown in FIG. 1 according to an embodiment of the present invention.

FIG. 3 illustrates a simple timing diagram for indicating signals shown in FIG. 2.

FIG. 4 illustrates a method of adjusting an operating voltage of a memory cell according to the measured capacitance result from the electrical oxide testing circuit 100 shown in FIG. 3 and an embodiment of the present invention.

### DETAILED DESCRIPTION

For eliminating the above-mentioned fabrication variation of memory cells, there are two optional strategies for the gate dielectric thickness of a memory cell, and there are also two other optional strategies for the gate length of the memory cell as well, where the strategies are utilized as criteria for retrieving an appropriate operating voltage for a memory cell in the present invention. Note that the operating voltage may be a program voltage or an erase voltage for the memory cell.

As for the gate dielectric thickness, a first strategy for achieving good data retention is to provide a low erase voltage to the memory cell with a thin gate dielectric thickness; and a second strategy for achieving an available and precise erase state is to provide a high erase voltage to the memory cell with a thick gate dielectric thickness of the memory cell.

As for the gate length, a first strategy for achieving an acceptable program state is to provide a low program voltage on the memory cell with a short gate length, thus it prevents disturbance from neighbored memory cells; and a second strategy is to provide a high program voltage on the memory cell with a long gate length.

By following the above four strategies, an operating voltage, which may be a program voltage or an erase voltage, can be adjusted in response to a corresponding gate length or a corresponding gate dielectric thickness, according to an embodiment of the present invention.

For performing the above-mentioned strategies, an available capacitance of the memory cell has to be measured in advance since the capacitance of the memory cell is directly related to the gate length or the gate dielectric thickness of the memory cell. For example, flat ONO capacitance and flat SP (standard performance)/IO oxide capacitance are used for determining the ONO thickness, i.e., the gate dielectric thickness of the memory cell; finger SP/IO oxide capacitance and flat SP/IO oxide capacitance are used for determining the PolyCD, i.e., the gate length. Besides, a higher capacitance indicates a longer gate length or a thinner gate dielectric thickness, and vice versa.

The present invention first discloses a memory including at least one memory cell and an electrical oxide testing circuit for measuring capacitance of an under-test capacitor of the at least one memory cell. The memory is also configured to adjust the operating voltage according to a measured capacitance result of the measured capacitance of the under-test capacitor, by following a disclosed adjusting method utilizing the above four strategies in the present invention. With the aid of the disclosed memory and the adjusting method, not only a precise capacitance of the memory cell can be measured, but an appropriate operating voltage corresponding to the measured capacitance result can also be determined for the memory cell.

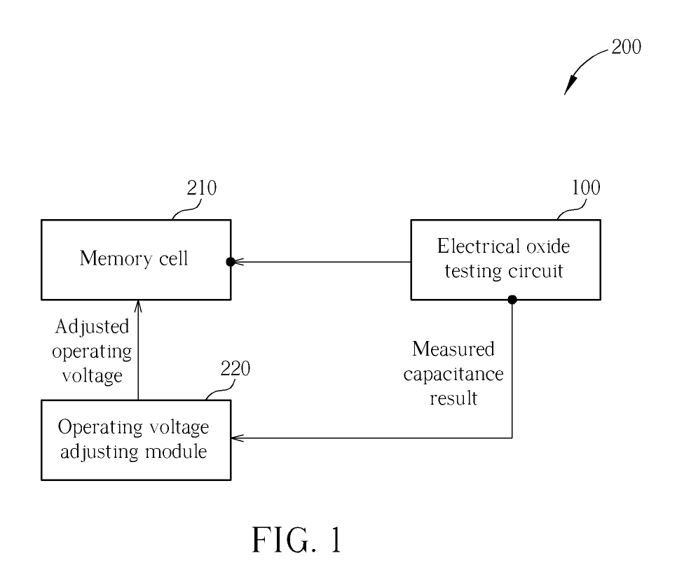

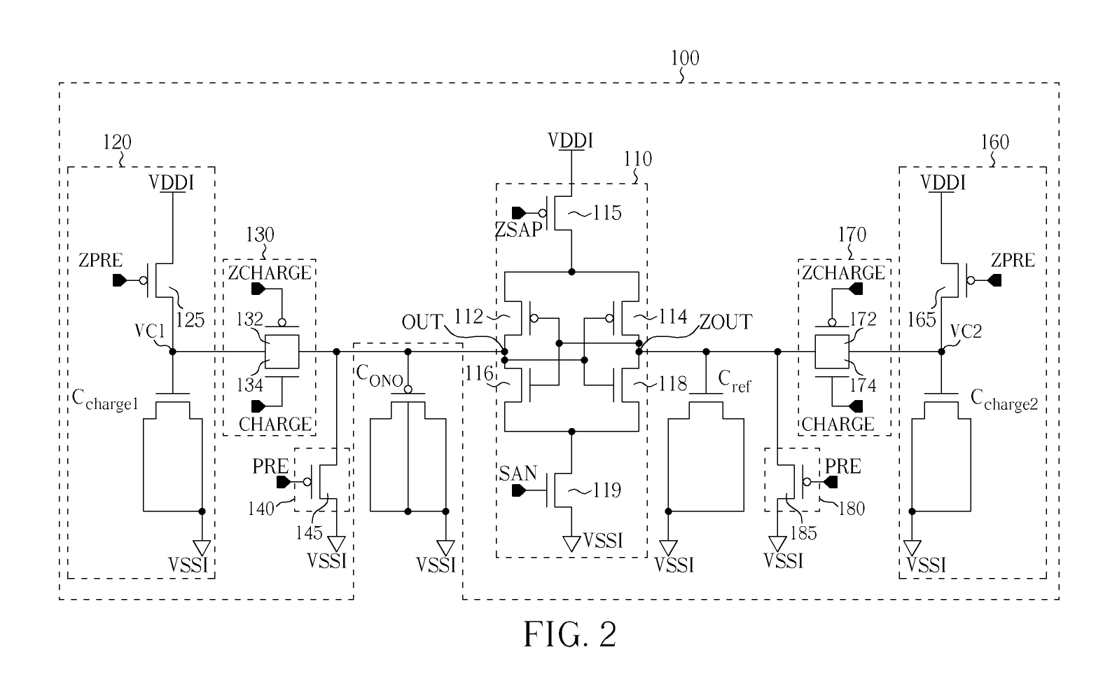

Please refer to FIG. 1, which illustrates a schematic diagram of a memory 200 according to an embodiment of the present invention. As shown in FIG. 1, the memory 200 includes a memory cell 210, an electrical oxide testing circuit 100, and an operating voltage adjusting module 220. Please also refer to FIG. 2, which illustrates the electrical oxide testing circuit 100 shown in FIG. 1 according to an embodiment of the present invention.

The electrical oxide testing circuit 100 is coupled to the memory cell 210. The electrical oxide testing circuit 100 is configured to test the electrical oxide characteristic of the memory cell 210. The electrical oxide testing circuit 100 retrieves voltages at the nodes OUT and ZOUT shown in FIG. 2 and generates a measured capacitance result according to the retrieved voltages at the nodes OUT and ZOUT. Note that the voltages at the nodes OUT and ZOUT can be utilized for referring to an capacitance of an under-test capacitor C_{ONO}, i.e., the capacitance of the memory cell 210, and a known reference capacitance of a reference capacitor C_{ref}, according to the above-mentioned correspondence between the capacitance of the memory cell and the gate length or the gate dielectric thickness.

Note that the reference capacitor C_{ref} is utilized as a standard to determine the characteristic of the memory cell, i.e. the gate length or the gate dielectric thickness which is related to the under-test capacitor C_{ONO}.

As shown in FIG. 2, the electrical oxide testing circuit 100 includes a differential amplifier 110, a reference capacitor C_{ref}, a first initialization circuit 120, a first transmission gate 130, a first discharging circuit 140, a second initialization circuit 160, a second transmission gate 170, and a second discharging circuit 180.

In the electrical oxide testing circuit 100, the capacitance of the under-test capacitor C_{ONO}) is compared with capacitance of the reference capacitor C_{ref}, by comparing voltages at the nodes OUT and ZOUT.

Both voltages at the capacitors C_{ONO} and C_{ref} are changed in the electrical oxide testing circuit 100 so as to render a higher voltage to be charged high, to render a low voltage to be discharged low. As a result, a voltage difference between both the voltages is amplified, so that the voltage at the node OUT can be differentiated from the voltage at the node ZOUT in a more precise manner.

As shown in FIG. 2, the differential amplifier 110 includes N-type MOSFETs 116, 118, 119, and P-type MOSFETs 112, 114, 115. The N-type MOSFET 116 has a drain coupled to the reference capacitor C_{ref}. The P-type MOSFET 112 has a drain coupled to the drain of the N-type MOSFET 116, and has a gate coupled to a gate of the N-type MOSFET 116. The N-type MOSFET 118 has a source coupled to a source of the N-type MOSFET 116, has a gate coupled to the drain of the N-type MOSFET 116, and has a drain coupled to the gate of the N-type MOSFET 116. The P-type MOSFET 114 has a gate coupled to the gate of the N-type MOSFET 118, has a source coupled to the source of the P-type MOSFET 112, and has a drain coupled to the drain of the N-type MOSFET 118. The N-type MOSFET 119 has a drain coupled to the source of the N-type MOSFET 116, has a gate coupled to a discharging signal SAN, and has a source coupled to a ground VSSI. The P-type MOSFET 115 has a drain coupled to the source of the P-type MOSFET 112, has a gate coupled to a charging signal ZSAP, and has a source coupled to a voltage source VDDI.

The first initialization circuit 120 is used for generating a first initialization voltage Vcharge1, and includes a P-type MOSFET 125 and a charging capacitor C_{charge1}. The P-type MOSFET 125 has a drain coupled to the charging capacitor C_{charge1}, has a gate coupled to a control signal ZPRE, and has a source coupled to the voltage source VDDI. The charging capacitor C_{charge1} has a first terminal coupled to the source of the P-type MOSFET 125 and a second terminal coupled to the ground VSSI, and is utilized for storing the initialization voltage Vcharge1 at a node VC1, which is located at the source of the P-type MOSFET 125.

The first discharging circuit 140 is used for discharging the under-test capacitor C_{ONO}, and may be implemented with an N-type MOSFET 145, which has a source coupled to the ground VSSI, has a gate coupled to a control signal PRE, and has a drain coupled to the under-test capacitor C_{ONO}.

The first transmission gate 130 is used for keeping the initialization voltage Vcharge1 at the node VC1, i.e., at the first initialization circuit 120 and for passing the initialization voltage Vcharge1 from the first initialization circuit 120 to the under-test capacitor C_{ONO}. The first transmission gate 130 includes an N-type MOSFET 134 and a P-type MOSFET 132. The N-type MOSFET 134 has a gate coupled to a control signal CHARGE, has a drain coupled to the first initialization circuit 120 at the node VC1, and has a source coupled to the differential amplifier 110 at a node OUT, which is located at the drain of the N-type MOSFET 116. The P-type MOSFET 132 has a source coupled to the drain of the N-type MOSFET 134, has a gate coupled to a control signal ZCHARGE, and has a drain coupled to the source of the N-type MOSFET 134.

The second initialization circuit 160 is basically the same as the first initialization circuit 120 in structure and functionality, so do the discharging circuits 140 and 180, or the transmission gates 130 and 170.

The second initialization circuit 160 is used for generating a second initialization voltage Vcharge2, and includes a charging capacitor C_{charge2} and a P-type MOSFET 165, where the charging capacitor C_{charge2} has a same capacitance with the charging capacitor C_{charge1}. The P-type MOSFET 165 has a drain coupled to the charging capacitor C_{charge2}, has a gate coupled to the control signal ZPRE, and has a source coupled to the voltage source VDDI. The charging capacitor C_{charge2} has a first terminal coupled to the source of the P-type MOSFET 165 and a second terminal coupled to the ground VSSI, and is utilized for storing the initialization voltage Vcharge2 at a node VC2, which is located at the source of the P-type MOSFET 165.

The second discharging circuit 180 is used for discharging the reference capacitor C_{ref}, and may be implemented with an N-type MOSFET 185, which has a source coupled to the ground VSSI, has a gate coupled to the control signal PRE, and has a drain coupled to the reference capacitor C_{ref}.

The second transmission gate 170 is used for keeping the initialization voltage Vcharge2 at a node VC2, i.e., at the second initialization circuit 160 and for passing the initialization voltage Vcharge2 from the second initialization circuit 160 to the reference capacitor C_{ref}. The second transmission gate 170 includes an N-type MOSFET 174 and a P-type MOSFET 172. The N-type MOSFET 174 has a gate coupled to the control signal CHARGE, has a drain coupled to the second initialization circuit 160 at the node VC2, and has a source coupled to the differential amplifier 110 at a node ZOUT, which is located at the drain of the N-type MOSFET 118. The P-type MOSFET 172 has a source coupled to the drain of the N-type MOSFET 174, has a gate coupled to the control signal ZCHARGE, and has a drain coupled to the source of the N-type MOSFET 174.

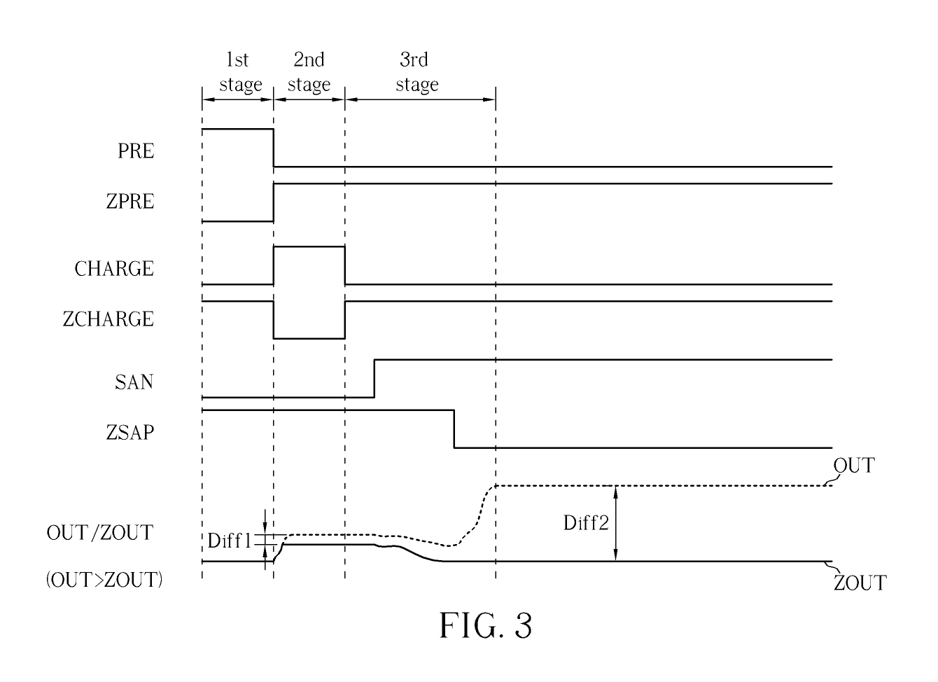

Please also refer to FIG. 3, which illustrates a simple timing diagram for indicating signals shown in FIG. 2. How the electrical oxide testing circuit 100 works is going to be explained with the aid of the timing diagram shown in FIG. 3. Note that the control signals PRE and ZPRE are logically-inverse to each other, and the control signals CHARGE and ZCHARGE are logically-inverse to each other. Also note that the OUT/ZOUT curve is specifically illustrated under a condition that the voltage at the node OUT is higher than the voltage at the node ZOUT, however, while the voltage at the node OUT is lower than the voltage at the node ZOUT, the curves of the nodes OUT/ZOUT are correspondingly exchanged with each other according to an embodiment of the present invention.

At a first stage, the voltages at the nodes VC1 and VC2 have to be initialized, therefore, the control signal ZPRE is set to a low voltage level, i.e., set to low. Since the control signal ZPRE is set to low, the P-type MOSFETs 125 and 165 are switched on so that the voltages Vcharge1 and Vcharge2 are respectively generated at the nodes VC1 and VC2 and respectively stored by the charging capacitors C_{charge1} and C_{charge2}. Note that the voltages Vcharge1 and Vcharge2 should be the same in voltage level since the initialization circuits 120 and 160 are the same in structure and functionality. At this time, since the control signal CHARGE is set to low and the control signal ZCHARGE is set to high, the N-type MOSFETs 134, 174 and the P-type MOSFETs 132 and 172 are all switched off, therefore the voltage Vcharge1 is kept at the node VC1, i.e., kept at the first initialization circuit 120, and the voltage Vcharge2 is kept at the node VC2, i.e., kept at the second initialization circuit 160. Besides, since the control signal PRE is set to high at this time, the N-type MOSFETs 145 and 185 are switched on so as to discharge the voltage levels at the nodes OUT and ZOUT respectively.

At a second stage, the control signal PRE is set to low, so that the N-type MOSFETs 145 and 185 are switched off to cease discharging the voltage levels at the nodes OUT and ZOUT respectively; the control signal ZPRE is set to high, so that both the P-type MOSFETs 125 and 165 are switched off and cease charging the voltage levels Vcharge1 and Vcharge2; the control signal CHARGE is set to high, and the control signal ZCHARGE is set to low, so that the N-type MOSFETs 134, 174 and the P-type MOSFETs 132 and 172 are all switched on, and as a result, the voltage Vcharge1 is passed from the first initialization circuit 120 to the under-test capacitor C_{ONO}, and the voltage Vcharge2 is passed from the second initialization circuit 160 to the reference capacitor C_{ref}.

Though the voltages Vcharge1 and Vcharge2 are the same in voltage level, since the capacitors C_{ref} and C_{ONO} are likely to differ in capacitance because of the fabrication procedure of the memory cell acquiring the under-test capacitor C_{ONO}, the voltage level at the nodes OUT and ZOUT may also correspondingly differ, as depicted by a difference Diff1 shown in FIG. 3. However, the difference Diff1 may be too small to easily confirm whether the capacitance of the under-test capacitor C_{ONO} is higher than the capacitance of the reference capacitor C_{ref} or not, therefore, in a third stage, the difference Diff1 is amplified in the electrical oxide testing circuit 100 to be the difference Diff2 for clearly confirming the under-test capacitor C_{ONO}.

Suppose under a first condition of the third stage, the voltage at the node OUT is higher than the voltage at the node ZOUT, and it suggests the condition that the gate dielectric thickness or the gate length of the memory cell 210 having the under-test capacitor C_{ONO} is thicker or shorter than standard, as discussed before while the voltage at the node OUT corresponds to the capacitance of the under-test capacitor C_{ONO}. As can be observed in FIG. 3, the discharging signal SAN is set to high so as to switch on the N-type MOSFET 119, and note that the charging signal is set to high at the same time so as to keep the P-type MOSFET 115 switched off. Since the voltage at the node OUT is currently higher than the voltage at the node ZOUT, the N-type MOSFET 118 is switched on because of a positive gate-to-drain bias voltage, whereas the N-type MOSFET 116 is switched off because of a negative gate-to-drain bias voltage. Therefore, the voltage at the node ZOUT is discharged by the N-type MOSFETs 119 and 118. The charging signal ZSAP is then set to low so as to switch on the P-type MOSFET 115. Since the voltage at the node OUT is currently higher than the voltage at the node ZOUT, the P-type MOSFET 112 is switched on because of a negative gate-to-drain bias voltage, whereas the P-type MOSFET 114 is switched off because of a positive gate-to-drain bias voltage, and therefore, the voltage at the node OUT is charged by the P-type MOSFETs 115 and 112. The adjustment is accomplished by charging the voltage at the node OUT and discharging the voltage at the node ZOUT, and as a result, the voltage difference between the nodes OUT and ZOUT is larger after the adjustment, as indicated by the difference Diff2 shown in FIG. 2. As a result, both the voltages at the nodes OUT and ZOUT shown in FIG. 1 can be utilized for indicating the fact that the capacitance of the under-test capacitor C_{ONO} is higher than the capacitance of the reference capacitor C_{ref} by what degree in a clearer manner, where the fact will be carried by the measured capacitance result and be interpreted by the operating voltage adjusting module 220 later.

Note that an order of switching on the N-type MOSFET 119 for discharging and switching on the P-type MOSFET 115 for charging can be alternative with respect to as shown in FIG. 2, i.e., the P-type MOSFET 115 may also be the first to be switched on before switching on the N-type MOSFET 119 in another embodiment of the present invention.

Under a second condition of the third stage, the voltage at the node OUT is lower than the voltage at the node ZOUT, and it suggests the condition that the gate dielectric thickness or the gate length of the memory cell 210 having the under-test capacitor C_{ONO} is thicker or longer than standard. Similarly, the discharging signal SAN is set to high so as to switch on the N-type MOSFET 119, and note that the charging signal is set to high at the same time so as to keep the P-type MOSFET 115 switched off. Since the voltage at the node OUT is currently lower than the voltage at the node ZOUT, the N-type MOSFET 116 is switched on because of a positive gate-to-drain bias voltage, whereas the N-type MOSFET 118 is switched off because of a negative gate-to-drain bias voltage. Therefore, the voltage at the node OUT is discharged by the N-type MOSFETs 119 and 116. The charging signal ZSAP is then set to low so as to switch on the P-type MOSFET 115. Since the voltage at the node ZOUT is currently higher than the voltage at the node ZOUT, the P-type MOSFET 114 is switched on because of a negative gate-to-drain bias voltage, whereas the P-type MOSFET 112 is switched off because of a positive gate-to-drain bias voltage, and therefore, the voltage at the node ZOUT is charged by the P-type MOSFETs 115 and 114. Similarly, the voltage difference between the nodes OUT and ZOUT is higher after the adjustment, as indicated by the difference Diff2 as well. As a result, both voltages at the nodes OUT and ZOUT are utilized for indicating the fact that the capacitance of the under-test capacitor C_{ONO} is lower than the capacitance of the reference capacitor C_{ref} by what degree in a clearer manner, where the fact will also be carried by the measured capacitance result interpreted by the operating voltage adjusting module 220 later by receiving the measured capacitance result.

Note that the degree by which the capacitance of the under-test capacitor C_{ONO} is higher or lower than the capacitance of the reference capacitor C_{ref} can be inducted by the electrical oxide testing circuit 100 according to both the known reference capacitance of the reference capacitor C_{ref} and a ratio between the voltages at the nodes OUT and ZOUT, according to one embodiment of the present invention.

As mentioned above, after the operating voltage adjusting module 220 receives the measured capacitance result from the electrical oxide testing circuit 100, a gate length or a gate dielectric thickness of the memory cell 210 can be determined according to the measured capacitance of the under-test capacitor C_{ONO}, by utilizing the correspondence between the capacitance of the memory cell 210 and the gate length or the gate dielectric thickness, so that whether the gate length or the gate dielectric thickness is thinner or thicker in comparison to a reference gate length or a reference gate oxide thickness indicated by the reference capacitor C_{ref} can be told by now.

As a result, the operating voltage adjusting module 220 is capable of determining how to provide an appropriate operating voltage to the memory cell 210 according to whether the gate length or the gate dielectric thickness is thinner or thicker and by following the above-mentioned four strategies.

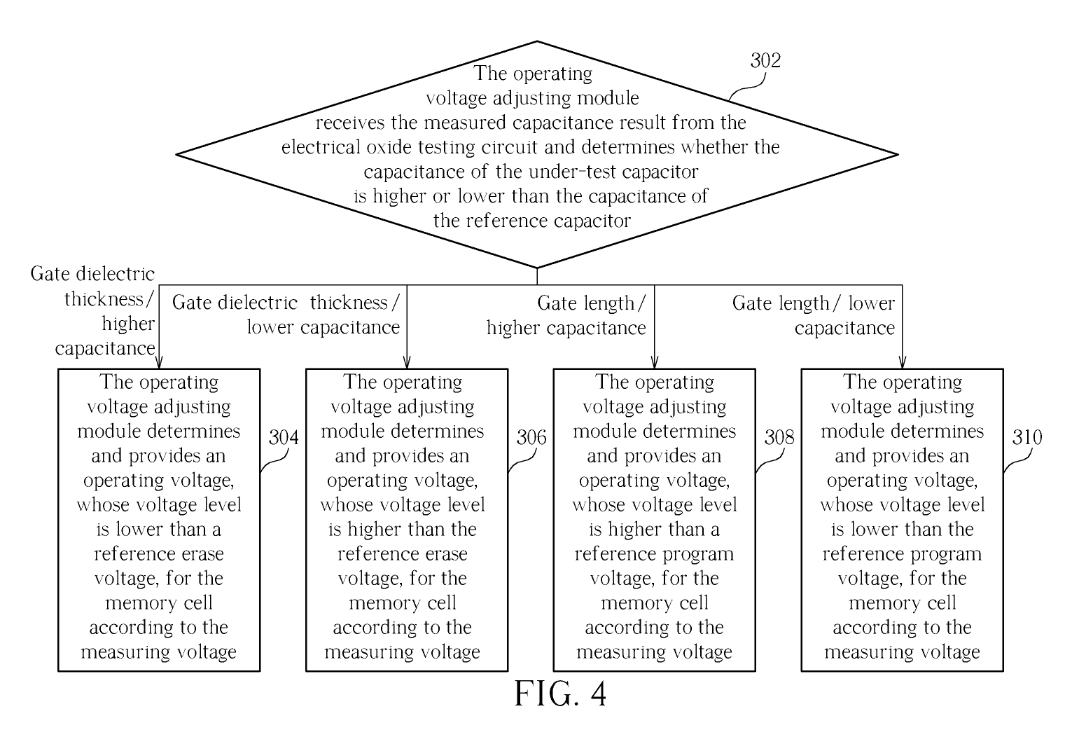

Please refer to FIG. 4, which illustrates a method of adjusting an operating voltage of a memory cell according to the measured capacitance result from the electrical oxide testing circuit 100 shown in FIG. 1 and an embodiment of the present invention. As shown in FIG. 4, the adjusting method includes steps as follows:

Step 302: The operating voltage adjusting module 220 receives the measured capacitance result from the electrical oxide testing circuit 100 and determines whether the capacitance of the under-test capacitor C_{ONO} is higher or lower than the capacitance of the reference capacitor C_{ref}; When the under-test capacitor C_{ONO} indicating a gate dielectric thickness of the memory cell 210 is higher than the capacitance of the reference capacitor C_{ref}, go to Step 304; when the under-test capacitor C_{ONO} indicating the gate dielectric thickness of the memory cell 210 is lower than the capacitance of the reference capacitor C_{ref}, go to Step 306; when the under-test capacitor C_{ONO} indicating a gate length of the memory cell 210 is higher than the capacitance of the reference capacitor C_{ref}, go to Step 308; and when the under-test capacitor C_{ONO} indicating the gate length of the memory cell 210 is lower than the capacitance of the reference capacitor C_{ref}, go to Step 310.

Step 304: The operating voltage adjusting module 220 determines and provides an operating voltage, whose voltage level is lower than a reference erase voltage, for the memory cell 210.

Step 306: The operating voltage adjusting module 220 determines and provides an operating voltage, whose voltage level is higher than the reference erase voltage, for the memory cell 210.

Step 308: The operating voltage adjusting module 220 determines and provides an operating voltage, whose voltage level is higher than a reference program voltage, for the memory cell 210.

Step 310: The operating voltage adjusting module 220 determines and provides an operating voltage, whose voltage level is lower than the reference program voltage, for the memory cell 210.

The steps illustrated in FIG. 4 are basically supported by the above descriptions and at least one embodiments of the present invention. However, embodiments generated by reasonable combinations and permutations, or by combining the above-mentioned limitations, should also be regarded as embodiments of the present invention.

The present invention discloses a memory and a related adjusting method for the disclosed memory. By testing the relative capacitors of the disclosed memory and by utilizing the disclosed adjusting method, no matter a gate length or a gate dielectric thickness of a memory cell varies because of process variation, the characteristic of the memory cell indicating a gate dielectric thickness or a gate length can always be determined according to a measured capacitance result, which is generated by amplifying a difference between capacitance of the reference capacitor and capacitance of the under-test capacitor, and thereby, an appropriate operating voltage for the memory cell can always be adjusted according to the measured capacitance result.

Those skilled in the art will readily observe that numerous modifications and alterations of the device and method may be made while retaining the teachings of the invention.

What is claimed is:

1. A memory, comprising:
a memory cell;
an electric oxide testing circuit for measuring capacitance of an under-test capacitor of the memory cell, so as to generate a measured capacitance result; and
an operating voltage adjusting module, for adjusting the operating voltage of the memory cell according to the measured capacitance result.

2. The memory of claim 1 wherein the electrical oxide testing circuit comprises:
a reference capacitor; and
a differential amplifier coupled to both an under-test capacitor of the memory cell and the reference capacitor, for amplifying a voltage difference between a first voltage stored by the under-test capacitor and a second voltage stored by the reference capacitor;
wherein both the first voltage and the second voltage are utilized for determining an under-test capacitance of the under-test capacitor, and a result of determining the under-test capacitance is carried by the measured capacitance result.

3. The memory of claim 2, wherein when the first voltage is higher than the second voltage, the first voltage is raised, and the second voltage is reduced.

4. The memory of claim 2, wherein when the first voltage is lower than the second voltage, the first voltage is reduced, and the second voltage is raised.

5. The memory of claim 2, wherein the differential amplifier comprises:
a first N-type MOSFET having a drain coupled to the reference capacitor;
a first P-type MOSFET having a drain coupled to the drain of the first N-type MOSFET, and having a gate coupled to a gate of the first N-type MOSFET;
a second N-type MOSFET having a source coupled to a source of the first N-type MOSFET, having a gate coupled to the drain of the first N-type MOSFET, and having a drain coupled to the gate of the first N-type MOSFET;
a second P-type MOSFET having a gate coupled to the gate of the second N-type MOSFET, having a source coupled to the source of the first P-type MOSFET, and having a drain coupled to the drain of the second N-type MOSFET;
a third N-type MOSFET having a drain coupled to the source of the first N-type MOSFET, having a gate coupled to a first discharging signal, and having a source coupled to ground; and
a third P-type MOSFET having a drain coupled to the source of the first P-type MOSFET, having a gate coupled to a charging signal, and having a source coupled to an under-test operating voltage.

6. The memory of claim 2, wherein the electrical oxide testing circuit further comprises:
a first initialization circuit for generating a first initialization voltage according to an under-test operating voltage;
a first transmission gate coupled to the first initialization circuit and the under-test capacitor, for keeping the first initialization voltage at the first initialization circuit or passing the first initialization voltage from the first initialization circuit to the under-test capacitor; and;
a first discharging circuit coupled to the under-test capacitor for discharging the under-test capacitor.

7. The memory of claim 6 wherein the first initialization circuit comprises:
a first charging capacitor for storing the first initialization voltage; and
a first P-type MOSFET having a drain coupled to the first charging capacitor, having a gate coupled to a first control signal, and having a source coupled to the under-test operating voltage.

8. The memory of claim 6 wherein the first discharging circuit comprises:
a first N-type MOSFET having a source coupled to ground, having a gate coupled to a second control signal, and having a drain coupled to the under-test capacitor.

9. The memory of claim 6 wherein the first transmission gate circuit comprises:
a second N-type MOSFET having a gate coupled to a third control signal, having a drain coupled to the first initialization circuit, and having a source coupled to the differential amplifier; and
a second P-type MOSFET having a source coupled to the drain of the second N-type MOSFET, having a gate coupled to a fourth control signal, and having a drain coupled to the source of the second N-type MOSFET.

10. The memory of claim 6 wherein the electrical oxide testing circuit further comprises:
a second initialization circuit for generating a second initialization voltage according to the under-test operating voltage;
a second transmission gate coupled to the second initialization circuit, for keeping the second initialization voltage at the second initialization circuit or passing the second initialization voltage from the second initialization circuit to the reference capacitor; and
a second discharging circuit coupled to the reference capacitor for discharging the reference capacitor.

11. The memory of claim 10 wherein the second initialization circuit comprises:
a second charging capacitor for storing the second initialization voltage; and
a third P-type MOSFET having a drain coupled to the second charging capacitor, having a gate coupled to the first control signal, and having a source coupled to the under-test operating voltage.

12. The memory of claim 10 wherein the second discharging circuit comprises a third N-type MOSFET having a source coupled to ground, having a gate coupled to the second control signal, and having a drain coupled to the reference capacitor.

13. The memory of claim 10 wherein the second transmission gate circuit comprises:
a fourth N-type MOSFET having a gate coupled to the third control signal, having a drain coupled to the second initialization circuit, and having a source coupled to the differential amplifier; and a fourth P-type MOSFET having a source coupled to the drain of the fourth N-type MOSFET, having a gate coupled to the fourth control signal, and having a drain coupled to the source of the fourth N-type MOSFET.

14. The memory of claim 10 wherein the first initialization circuit comprises:
a first charging capacitor for storing the first initialization voltage; and
a first P-type MOSFET having a drain coupled to the first charging capacitor, having a gate coupled to a first control signal, and having a source coupled to a voltage source;
wherein the first discharging circuit comprises a first N-type MOSFET having a source coupled to ground, having a gate coupled to a second control signal, and having a drain coupled to the under-test capacitor;
wherein the first transmission gate circuit comprises:
a second N-type MOSFET having a gate coupled to a third control signal, having a drain coupled to the drain of the first P-type MOSFET, and having a source coupled to the drain of the first N-type MOSFET; and
a second P-type MOSFET having a source coupled to the drain of the second N-type MOSFET, having a gate coupled to a fourth control signal, and having a drain coupled to the source of the second N-type MOSFET;
wherein the second initialization circuit comprises:
a second charging capacitor for storing the second initialization voltage; and
a third P-type MOSFET having a drain coupled to the second charging capacitor, having a gate coupled to the first control signal, and having a source coupled to the voltage source;
wherein the second discharging circuit comprises a third N-type MOSFET having a source coupled to ground, having a gate coupled to the second control signal, and having a drain coupled to the reference capacitor;
wherein the second transmission gate circuit comprises:
a fourth N-type MOSFET having a gate coupled to the third control signal, having a drain coupled to the drain of the third P-type MOSFET, and having a source coupled to the drain of the third N-type MOSFET; and
a fourth P-type MOSFET having a source coupled to the drain of the fourth N-type MOSFET, having a gate coupled to the fourth control signal, and having a drain coupled to the source of the fourth N-type MOSFET; and
wherein the first control signal is an inverse signal to the second control signal, the third control signal is an inverse signal to the fourth signal, and the first charging capacitor has a same capacitance as the second charging capacitor.

15. The memory of claim 1 wherein whether capacitance of an under-test capacitor of the memory cell is higher or lower than capacitance of a reference capacitor is determined according to the measured capacitance result.

16. The memory of claim 15 wherein the operating voltage adjusting module is configured to adjust the operating voltage to be lower than a reference erase voltage, when the capacitance of the under-test capacitor indicating the characteristic of a gate dielectric of the memory cell is higher than the capacitance of the reference capacitor.

17. The memory of claim 15 wherein the operating voltage adjusting module is configured to adjust the operating voltage to be higher than a reference erase voltage, when capacitance of the under-test capacitor indicating the characteristic of a gate dielectric of the memory cell is lower than the capacitance of the reference capacitor.

18. The memory of claim 15 wherein the operating voltage adjusting module is configured to adjust the operating voltage to be higher than a reference program voltage and to provide the adjusted operating voltage to the memory cell, when capacitance of the under-test capacitor indicating a gate length of the memory cell is higher than the capacitance of the reference capacitor.

19. The memory of claim 15 wherein the operating voltage adjusting module is configured to adjust the operating voltage to be lower than a reference program voltage and to provide the adjusted operating voltage to the memory cell, when capacitance of the under-test capacitor indicating a gate length of the memory cell is lower than the capacitance of the reference capacitor.

20. The memory of claim 1 wherein the operating voltage of the memory cell is a program voltage or an erase voltage of the memory cell.

21. A method for determining an operating voltage of a memory cell, the method comprising:
measuring an under-test capacitor which indicating the characteristic of the gate dielectric of the memory cell or the characteristic of the SP/IO oxide to generate a measured capacitance result; and
adjusting the operating voltage of the memory cell according to the measured capacitance result.

22. The method of claim 21 wherein the characteristic of the gate dielectric of the memory cell refers to the gate dielectric thickness of the memory cell.

23. The method of claim 22 wherein adjusting the operating voltage of the memory cell according to the measured capacitance result comprises:
adjusting the operating voltage to be lower than a reference erase voltage and to provide the adjusted operating voltage to the memory cell, when capacitance of the under-test capacitor is higher than the capacitance of the reference capacitor.

24. The method of claim 22 wherein adjusting the operating voltage of the memory cell according to the measured capacitance result comprises:
adjusting the operating voltage to be higher than a reference erase voltage and to provide the adjusted operating voltage to the memory cell, when capacitance of the under-test capacitor is lower than the capacitance of the reference capacitor.

25. The method of claim 22 wherein the operating voltage of the memory cell is an erase voltage of the memory cell.

26. The method of claim 21 wherein the characteristic of the SP/IO oxide refers to the gate length of the memory cell.

27. The method of claim 26 wherein adjusting the operating voltage of the memory cell according to the measured capacitance result comprises:
adjusting the operating voltage to be higher than a reference program voltage and to provide the adjusted operating voltage to the memory cell, when capacitance of the under-test capacitor is higher than the capacitance of the reference capacitor.

28. The method of claim 26 wherein adjusting the operating voltage of the memory cell according to the measured capacitance result comprises:
adjusting the operating voltage to be higher than a reference gate voltage and to provide the adjusted operating voltage to the memory cell, when capacitance of the under-test capacitor is lower than the capacitance of the reference capacitor.

29. The method of claim 26 wherein the operating voltage of the memory cell is a program voltage of the memory cell.
